(19) United States
(12) Patent Application Publication
(10) Pub. No.: US 2006/0145056 A1
(43) Pub. Date: Jul. 6, 2006

(54) Image sensor having diffractive lens and method for fabricating the same

(76) Inventor: Sun Wook Jung, Yeoju-gun (KR)

Correspondence Address: MCKENNA LONG & ALDRIDGE LLP;Song K. Jung, 1900 K Street, N.W., Washington, DC, 20006, US

(21) Appl. No.: 11/319,498

(22) Filed: Dec. 29, 2005

(30) Foreign Application Priority Data
Dec. 30, 2004 (KR) P 2004-0116469

(51) Int. Cl. H01L 27/00

(52) U.S. Cl. 250/208.1

(57) ABSTRACT

An image sensor including a diffractive lens simplifies a fabrication process and minimizes loss. The image sensor includes a diffractive lens as an inner lens between a color filter portion and a photodiode for compensating sensitivity to a light received. A method for fabricating the image sensor includes forming a diffractive lens as an inner lens between a color filter portion and a photodiode for compensating a sensitivity to a light received.

This application claims the benefit of Korean Application No. 10-2004-0116469, filed on Dec. 30, 2004, which is hereby incorporated by reference for all purposes as if fully set forth herein.

### BACKGROUND OF THE INVENTION

1. Field of the Invention

The present invention relates to an image sensor having a diffractive lens and a method for fabricating the same, and more particularly, to an image sensor having a diffractive lens that simplifies a fabrication process and minimizes a light loss.

2. Discussion of the Related Art

An image sensor is a semiconductor module for converting an optical image into an electric signal. The electric signal may be stored, transmitted, or displayed. Such image sensors may be categorized as a charge-coupled device (CCD), which is based on a silicon semiconductor, or a complementary metal-oxide-semiconductor (CMOS). CCD image sensors and CMOS image sensors both use photodiodes in detecting incident light. To form a color image sensor, a color filter array layer is provided above a corresponding array of photodiodes.

An optical microlens system for enhancing a light receptive capability of the image sensor uses a diffractive lens. The diffractive lens diffracts light incident on a lens surface and focuses the light onto a photodiode disposed under the lens. The lens is fabricated by forming a photoresist pattern for a lens portion, based on a conventional etching process, and subjecting the pattern to a heating process for shaping the pattern into a convex lens shape. The heating process, however, is limited in forming patterns of less than 365 nm, i.e., the limit of resolution of an I-line light source, which is the typical light source currently used in patterning.

### SUMMARY OF THE INVENTION

Accordingly, the present invention is directed to an image sensor having a diffractive lens and a method for fabricating the same and that substantially obviates one or more of the problems due to limitations and disadvantages of the related art.

An advantage of the present invention is to provide an image sensor which has a simple structure.

An advantage of the present invention is to provide an image sensor which enhances resolution characteristics.

An advantage of the present invention is to provide an image sensor which reduces the number of layers to be formed during fabrication.

An advantage of the present invention is to provide an image sensor which minimizes a light loss.

An advantage of the present invention is to provide a method for fabricating the above image sensor.

Additional features and advantages of the invention will be set forth in the description which follows, and in part will be apparent from the description, or may be learned by practice of the invention. The objectives and other advantages of the invention will be realized and attained by the structure and method particularly pointed out in the written description and claims hereof as well as the appended drawings.

To achieve these and other advantages and in accordance with the purpose of the present invention, as embodied and broadly described, there is provided an image sensor comprising a diffractive lens as an inner lens between a color filter portion and a photodiode for compensating sensitivity to a light received.

In another aspect of the present invention, there is provided a method for fabricating an image sensor comprising forming a diffractive lens as an inner lens between a color filter portion and a photodiode for compensating a sensitivity to a light received.

In another aspect of the present invention, forming the diffractive lens comprises forming a light transmissive layer which transmits light received at a photodiode; forming a planarizing layer on the light transmissive layer for forming a layer thereon; coating the planarizing layer with photoresist and forming a diffractive pattern using the photoresist; and etching the diffractive pattern.

In another aspect of the present invention, there is provided an image sensor comprising a photodiode region including a plurality of photodiodes; a planarizing layer on the photodiode region; and an inner lens layer on the planarizing layer, wherein the inner lens layer comprises a plurality of diffractive lenses corresponding to the plurality of photodiodes.

In another aspect of the present invention, the image sensor further comprises a color filter layer including a plurality of color filters on the inner lens layer.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiment(s) of the invention and together with the description serve to explain the principles of the invention. In the drawings:

FIG. 1 is a conceptual diagram of an image sensor having a diffractive lens in accordance with an embodiment of the present invention; and

FIG. 2 is a plan view of a zone plate of a diffractive lens in accordance with an embodiment of the present invention.

### DETAILED DESCRIPTION OF THE INVENTION

Reference will now be made in detail to embodiments of the present invention, examples of which are illustrated in the accompanying drawings. Wherever possible, like reference designations will be used throughout the drawings to refer to the same or similar parts.

The image sensor of the present invention is fabricated by forming a photodiode, which converts a light signal into an electrical signal, on a silicon substrate by a conventional CMOS or CCD process, and forming a gate and wiring layer for enabling a readout operation. Then, a color filter is formed on the thus-fabricated image sensor by an on-chip method. The color filter is formed as a color image sensor to enable color separation. A metal wiring layer serves as a light shield.

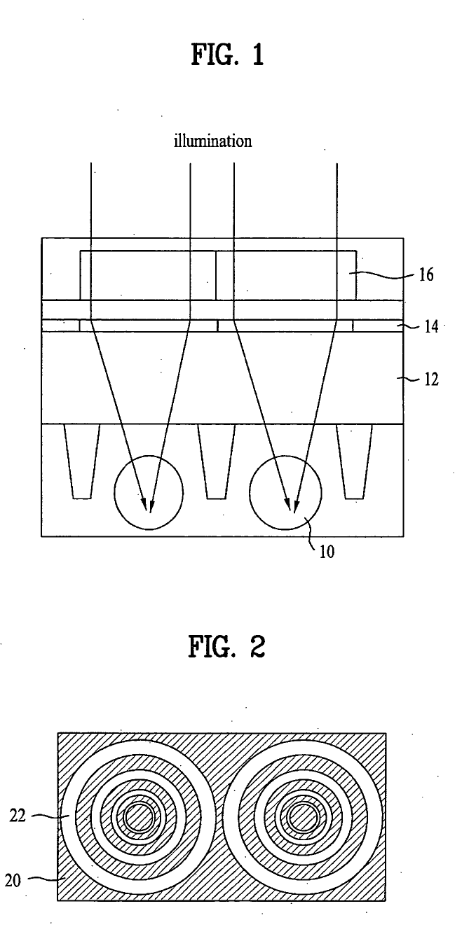

FIG. 1 illustrates an image sensor having a diffractive lens. The image sensor includes a photodiode region 10 including photodiodes disposed at a lower portion of the image sensor; a planarizing layer 12 formed over the photodiode region 10; an inner lens layer 14 including a number of diffractive lenses corresponding to the photodiodes of the photodiode region 10 formed on the planarizing layer 12; and a color filter layer 16 including color filters formed on the inner lens layer 14. The planarizing layer 12 provides a surface on which to form an upper layer while transmitting light to the photodiode region 10. Light transmitted through the color filters of the color filter layer 16 is converged by the diffractive lenses of the inner lens layer 14 and is delivered to the photodiode region 10 through the underlying planarizing layer 12.

The image sensor is completed by forming a metal wiring layer, i.e., a light-shielding layer, which is performed as a final process, resulting in a step roughly equal to the thickness of the metal wiring layer. The planarizing layer 12 is needed to overcome the step, i.e., an uneven portion. The planarizing layer 12 is subjected to passivation using a material of a silicon dioxide group or a material of a silicon nitride group, to protect the metal wiring and improve reliability. An embodiment of the present invention uses the material of the silicon dioxide group coated to a thickness of 0.5˜2.0 μm. Planarization provides a level surface for receiving the inner lens layer 14 and the color filter layer 16, which are subsequently formed on the planarizing layer 12. The planarized material, which is planarized by chemical-mechanical polishing or a dry etch-back process, may be any material that exhibits an appropriate refractive index and good transmissivity of visible wavelengths. The planarized surface is coated with photoresist to a thickness of 1.0˜0.5 μm, and the photoresist is subjected to photolithography for forming the diffractive pattern.

FIG. 2 illustrates a zone plate of a diffractive lens in accordance with an embodiment of the present invention. Dark areas 20 in the zone plate denote unetched portions, i.e., remaining photoresist, and light areas 22 denote etched portions. Such a diffractive lens can be fabricated by a conventional method, resulting in the formation of a series of gradually increasing steps across the diffractive lens. For example, the diffractive lens can be fabricated using a variety of photo-masks. The diffractive lens can also be fabricated using either a grayscale mask or a black/white mask. A grayscale mask is a variation of a black/white mask and differentiates a quantity of transmitted light and enables forming a desired section of a diffractive lens. The black/white mask forms a stair-like or stepped section by using a multi-stepped black/white mask.

If stacked photodiodes are used, a focal point may be changed by changing the size of the zone plate to vary the point at which the focused light meets a given photodiode of the stack after transmission through a silicon surface. The stacked photodiodes enable a narrow-band response at the focal point when there is no color filter.

Thereafter, the color filter can be fabricated by a conventional color filter fabricating method. For example, after forming the diffractive lens, a planarizing process is performed for forming the color filter. Because the photodiode itself is insensitive to color differentiation, the color filter portion may be formed of an organic material for selective adjustment of color information for each pixel.

The formation of a plurality of microlenses on the color filter array may be omitted in an image sensor according to the present invention since the diffractive lens performs an adequate compensation of the received light. Such microlenses may nevertheless be additionally provided on the color filter layer as desired.

By adopting the image sensor of the present invention, in which an inner lens is provided as a diffractive lens, a fabrication process can be simplified by eliminating a thermal process. Moreover, the loss of light energy in an optical signal traveling through a lens system can be reduced by a phase inversion of a blocking region.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. An image sensor comprising:
a diffractive lens as an inner lens between a color filter portion and a photodiode for compensating sensitivity to a light received.

2. The image sensor of claim 1, wherein the color filter portion includes an organic material for selective adjustment of color information.

3. A method for fabricating an image sensor comprising:
forming a diffractive lens as an inner lens between a color filter portion and a photodiode for compensating a sensitivity to a light received.

4. The method of claim 3, wherein the color filter portion includes an organic material for selective adjustment of color information.

5. The method of claim 3, wherein forming a diffractive lens comprises:
forming a light transmissive layer which transmits light received at a photodiode;
forming a planarizing layer on the light transmissive layer for forming a layer thereon;
coating the planarizing layer with photoresist and forming a diffractive pattern using the photoresist; and
etching the diffractive pattern.

6. The method of claim 5, wherein a grayscale mask is used to form the diffractive lens.

7. The method of claim 5, wherein a black/white mask is used to form the diffractive lens.

8. The method of claim 5, further comprising:
planarizing the planarizing layer using chemical mechanical polishing.

9. The method of claim 5, further comprising:
planarizing the planarizing layer using a dry etch-back process.

10. An image sensor comprising:
a photodiode region including a plurality of photodiodes;
a planarizing layer on the photodiode region; and
an inner lens layer on the planarizing layer, wherein the inner lens layer comprises a plurality of diffractive lenses corresponding to the plurality of photodiodes.

11. The image sensor of claim 10, further comprising:
a color filter layer including a plurality of color filters on the inner lens layer.
